(19) United States
(12) Patent Application Publication
(10) Pub. No.: US 2012/0025326 A1
(43) Pub. Date: Feb. 2, 2012

(54) SEMICONDUCTOR DEVICE AND MANUFACTURING METHOD THEREOF

(75) Inventors: Hiroshi NAKAGAWA, Toyama (JP); Jun SUZUKI, Toyama (JP)

(73) Assignee: Panasonic Corporation, Osaka (JP)

(21) Appl. No.: 13/269,818

(22) Filed: Oct. 10, 2011

Related U.S. Application Data
(63) Continuation of application No. PCT/JP2010/000103, filed on Jan. 12, 2010.

(30) Foreign Application Priority Data
Jun. 2, 2009 (JP) 2009-133473

(51) Int. Cl. H01L 29/78; H01L 21/336

(52) U.S. Cl. 257/410; 438/591; 257/E29.255; 257/E21.409

(57) ABSTRACT

An interface oxide layer, a gate insulating film, and a gate electrode are sequentially provided on the upper surface of a semiconductor substrate. The gate insulating film has a first high-k film and a second high-k film. The first high-k film is provided on the interface oxide layer, and contains nitrogen. The second high-k film is provided on the first high-k film, and contains nitrogen. The first high-k film has a lower nitrogen concentration than the second high-k film.

### CROSS-REFERENCE TO RELATED APPLICATION

This is a continuation of PCT International Application PCT/JP2010/000103 filed on Jan. 12, 2010, which claims priority to Japanese Patent Application No. 2009-133473 filed on Jun. 2, 2009. The disclosures of these applications including the specifications, the drawings, and the claims are hereby incorporated by reference in their entirety.

### BACKGROUND

The present disclosure relates to semiconductor devices and manufacturing methods thereof, and more particularly to semiconductor devices having a high-k film as a gate insulating film and manufacturing methods thereof.

As the operational speed of metal oxide semiconductor field effect transistors (MOSFETs) increases, the transistor size has been reduced according to the constant electric field scaling law. Capability of the MOSFETs can be represented by current driving capability Gm, which is proportional to the carrier mobility μ, the gate width W, and the capacitance Cox of a capacitor (which is formed by a gate electrode, a gate insulating film, and a silicon substrate) and is inversely proportional to the gate length L. The capacitance Cox of the capacitor is represented by Cox=∈₀·∈·(S/d) (where ∈₀: dielectric constant in vacuum, ∈: relative dielectric constant of the gate insulating film, S: gate area, and d: thickness of the gate insulating film). Thus, the capability of the MOSFETs can be improved by reducing the thickness d of the gate insulating film or by reducing the gate length L. Accordingly, the gate insulating film, which is a silicon oxide film, a silicon oxynitride film, etc., is reduced in thickness, and the gate length of the gate electrode made of polysilicon etc. is reduced in order to improve the capability of the MOSFETs.

However, improving the capability of the MOSFETs has the following problems. Reducing the thickness of the gate insulating film to 2 nm or less increases a direct tunneling current, thereby significantly reducing dielectric strength of the gate insulating film upon application of a gate voltage. This increases power consumption of the MOSFETs. Thus, reducing the thickness of the gate insulating film makes it difficult to improve the capability of the MOSFETs and to reduce the power consumption of the MOSFETs.

As described above, the capacitance Cox of the capacitor is represented by Cox=∈₀·∈·(S/d). Since the use of a high-k gate insulating film (a high-k film) having a larger relative dielectric constant than a conventional silicon oxide film (∈: 3.9) and a conventional silicon oxynitride film (∈: 3.9-7) as the gate insulating film can increase the physical thickness of the gate insulating film while maintaining effective gate capacitance, the direct tunneling current can be reduced.

A hafnium oxide film (a Hfo₂ film), a zirconium oxide film (a ZrO₂ film), an alumina film (an Al₂O₃ film), a film made of a rare earth metal oxide, etc. have received attention as the high-k film, and silicate films and aluminate films of these materials also have received attention as the high-k film. Of these films, a Hfo₂ film and a HfSiO film are the most promising as a next-generation high-k gate insulating film, because these films have a relatively high relative dielectric constant, a bandgap of 5 eV or more, and a great electron barrier height for the silicon substrate.

Moreover, as the size of the MOSFETs is reduced, depletion of polysilicon gate electrodes cannot be ignored, and it is difficult to increase the gate capacitance. The polysilicon gate electrodes are therefore increasingly replaced with metal gate electrodes (the influence of a depletion layer can be ignored). Thus, a structure in which a metal electrode is formed on a high-k film is promising as a next-generation gate structure.

### SUMMARY

High-k films are typically formed at a low temperature. Thus, after a Hfo₂ film and a HfSiO film are formed, high temperature annealing (post-deposition annealing (PDA)) is performed in an atmosphere of oxygen and nitrogen. This high temperature annealing can make the high-k film dense, and can also compensate for oxygen deficiency in the high-k film.

However, this high temperature annealing can cause crystallization of the high-k film or phase separation in the high-k film. This problem can also be caused by rapid thermal annealing that is performed to activate boron or phosphorus implanted into the gate electrode. As crystallization of the high-k film or phase separation in the high-k film proceeds, a leakage current may flow through grain boundaries that are present in the high-k film, and capacitance of the gate insulating film varies due to a non-uniform relative dielectric constant in the gate insulating film. As a solution to such problems, it is known to dope the high-k film with nitrogen. This can improve thermal stability of the high-k film.

However, when nitriding the high-k film, nitrogen atoms reach the interface with the semiconductor substrate from the high-k film, and bond with semiconductor (silicon in many cases) of the semiconductor substrate. This can occur even if a heat treatment is performed on the semiconductor substrate. This results in an increase in defect density at the interface between the semiconductor substrate and the high-k film, a variation in threshold voltage due to fixed charges that are present in the high-k film, reduction in carrier mobility, etc. That is, characteristics of the MOSFETs are degraded.

The present disclosure was developed in view of the above problems, and it is an object of the present disclosure to implement reduction in device size without degrading capability of a semiconductor device, in the semiconductor device using a high-k film as a gate insulating film and a manufacturing method thereof.

According to a semiconductor device of the present disclosure, an interface oxide layer, a gate insulating film, and a gate electrode are sequentially provided on an upper surface of a semiconductor substrate. The gate insulating film has a first high-k film provided on the interface oxide layer, and a second high-k film provided on the first high-k film. The first and second high-k films contain nitrogen, and the first high-k film has a lower nitrogen concentration than the second high-k film.

In such a semiconductor device, diffusion of the nitrogen to an interface between the semiconductor substrate and the interface oxide layer can be prevented as compared to a semiconductor device that does not include the first high-k film.

Moreover, in such a semiconductor device, crystallization and phase separation in the high-k film during a heat treatment can be suppressed as compared to a semiconductor device that does not include the second high-k film.

In the semiconductor device of the present disclosure, it is preferable that the first high-k film contain hafnium and oxygen, and that the second high-k film contain hafnium and oxygen. It is also preferable that the first high-k film and the second high-k film satisfy b/a≦1, where “a” represents an atom ratio of the oxygen to the hafnium in the first high-k film, and “b” represents an atom ratio of the oxygen to the hafnium in the second high-k film. Thus, the nitrogen concentration in the first high-k film can be made lower than that in the second high-k film by using a relatively simple method.

In a preferred embodiment described below, the first high-k film contains a first metal different from the hafnium, the second high-k film contains a second metal different from the hafnium, and the first and second metals are at least one of Al, La, Zr, Ti, Ta, Mg, Ge, and Y.

According to a method for manufacturing a semiconductor device of the present disclosure, an interface oxide layer, a gate insulating film, and a gate electrode are sequentially provided on an upper surface of a semiconductor substrate. At this time, in a step of providing the gate insulating film, first and second high-k material films are sequentially provided on the interface oxide layer, and then the first high-k material film is doped with nitrogen to form a first high-k film, and the second high-k material film is doped with nitrogen to form a second high-k film having a higher nitrogen concentration than the first high-k film.

In the method of the present disclosure, it is preferable that the first high-k material film be formed by using a first gas including hafnium and a first oxidant including oxygen, and that the second high-k material film be formed by using a second gas including hafnium and a second oxidant including oxygen. At this time, the first high-k material film and the second high-k material film are preferably formed so as to satisfy b/a≦1, where “a” represents an atom ratio of the oxygen to the hafnium in the first high-k material film, and “b” represents an atom ratio of the oxygen to the hafnium in the second high-k material film. Thus, an oxygen concentration in the first high-k material film can be made higher than that in the second high-k material film. Accordingly, the amount of nitrogen with which the first high-k material film is doped can be made smaller than that of nitrogen with which the second high-k material film is doped.

In the method of the present disclosure, a step of supplying the first gas to an upper surface of the interface oxide layer for a first time, and a step of supplying the first oxidant to the upper surface of the interface oxide layer for a second time can be repeatedly performed in the step of forming the first high-k material film, and a step of supplying the second gas to an upper surface of the first high-k material film for a third time, and a step of supplying the second oxidant to the upper surface of the first high-k material film for a fourth time can be repeatedly performed in the step of forming the second high-k material film. One of the following two methods can be selected in order to satisfy b/a≦1. In a first method, the same gas is used as the first gas and the second gas, the same oxidant is used as the first oxidant and the second oxidant, and the second time is made longer than the fourth time. In a second method, tetrakis(dimethylamino)hafnium is used as the first gas, ozone is used as the first oxidant, tetrachlorohafnium is used as the second gas, and water is used as the second oxidant.

According to the present disclosure, the semiconductor device can be reduced in size without degrading capability thereof.

### BRIEF DESCRIPTION OF THE DRAWINGS

FIGS. 1A, 1C, and 1E are cross-sectional views of a semiconductor device according to an embodiment of the present disclosure, FIGS. 1B, 1D, and 1F are graphs showing a nitrogen concentration profile in the semiconductor device shown in FIGS. 1A, 1C, and 1E, respectively.

FIGS. 2A-2E are cross-sectional views sequentially illustrating the steps of a method for manufacturing the semiconductor device according to the embodiment of the present disclosure.

FIG. 3 is a graph showing the relation between the thickness of a HfSiO film and the o/Hf atom ratio in the HfSiO film.

FIG. 4 is a graph showing the relation between the thickness of the HfSiO film and the nitrogen concentration in the HfSiO film.

FIG. 5 is a graph showing the relation between an equivalent oxide thickness (EOT) and a leakage current Jg.

### DETAILED DESCRIPTION

A semiconductor device and a manufacturing method thereof according to an embodiment of the present disclosure will be described below with reference to the accompanying drawings. Note that the present disclosure is not limited to the following embodiment.

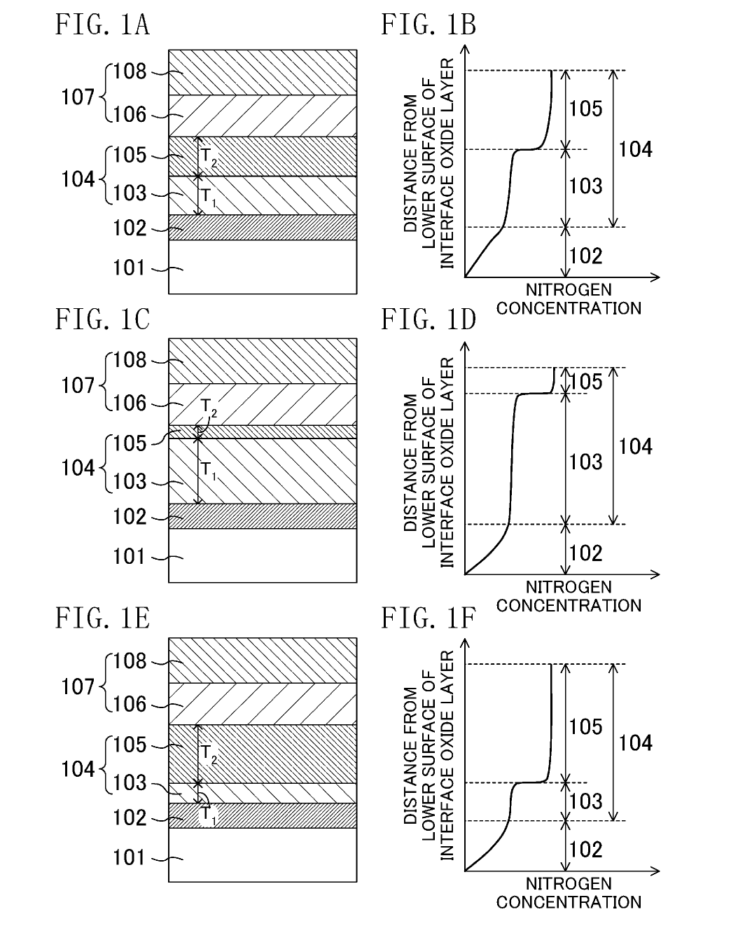

FIGS. 1A, 1C, and 1E are cross-sectional views of a semiconductor device according to an embodiment of the present disclosure, and FIGS. 1B, 1D, and 1F are graphs showing a nitrogen concentration profile in the semiconductor device shown in FIGS. 1A, 1C, and 1E, respectively.

As shown in FIGS. 1A, 1C, and 1E, in the semiconductor device of the present embodiment, an interface oxide layer 102, a gate insulating film 14, and a gate electrode 107 are sequentially provided in this order on the upper surface of a semiconductor substrate 101 made of silicon, etc.

The interface oxide layer 102 is a silicon oxide film or a silicon oxynitride film, and has a thickness of 1.5 nm or less. The gate electrode 107 is formed by a metal gate electrode 106 and a polysilicon electrode 108. The metal electrode 106 is provided on the upper surface of the gate insulating film 104, and is made of, e.g., TiN, TiAlN, TaC, or TaCN.

The polysilicon electrode 108 is provided on the upper surface of the metal gate electrode 106, and contains impurities such as arsenic, boron, etc. The gate insulating film 104 will be described in detail below.

The gate insulating film 104 is formed by a first high-k film 103 and a second high-k film 105. The first high-k film 103 is provided on the upper surface of the interface oxide layer 102, and is a HfO₂ or HfSiO film containing nitrogen. The second high-k film 105 is provided on the upper surface of the first high-k film 103, and is a HfO₂ or HfSiO film containing nitrogen.

It is preferable that the nitrogen concentration in the first high-k film 103 be lower than that of the second high-k film 105, and that the difference therebetween be 1 atm % or less. This can prevent diffusion of nitrogen from the gate insulating film 104 into the semiconductor substrate 101.

Specifically, in the case where the gate insulating film is formed by only the second high-k film, the second high-k film (a high-k film having a high nitrogen concentration) contacts the interface oxide layer. In such a semiconductor device, nitrogen diffuses from the gate insulating film to the interface between the interface oxide layer and the semiconductor substrate, whereby nitrogen may bond with semiconductor of the semiconductor substrate. This degrades MOSFET characteristics.

In the case where the gate insulating film is formed by only the first high-k film, diffusion of nitrogen into the semiconductor substrate can be prevented. In this case, however, performing a heat treatment after formation of the gate insulating film may cause crystallization of the HfSiO film, phase separation in the HfSiO film, penetration of impurities through the HfSiO film, etc. In this case, it is difficult to compensate for oxygen deficiency in the HfSiO film, etc.

In the present embodiment, the first high-k film 103 is provided between the interface oxide layer 102 and the second high-k film 105. That is, the first high-k film 103 contacts the interface oxide layer 102. Thus, in the semiconductor device of the present embodiment, diffusion of nitrogen from the gate insulating film 104 to the interface between the interface oxide layer 102 and the semiconductor substrate 101 can be suppressed, whereby bonding of the nitrogen with semiconductor (silicon in the present embodiment) of the semiconductor substrate 101 can be suppressed. Accordingly, an increase in defect density in the interface between the semiconductor substrate 101 and the gate insulating film 104 can be prevented, a variation in threshold voltage due to fixed charges that are present in the first high-k film 103 and the second high-k film 105 can be prevented, and reduction in carrier mobility, etc. can be prevented. That is, degradation in MOSFET characteristics can be prevented.

In the present embodiment, the second high-k film 105 is provided on the upper surface of the first high-k film 103. Thus, in the semiconductor device of the present embodiment, crystallization of the HfSiO film in the gate insulating film 104, phase separation in the HfSiO film in the gate insulating film 104, and penetration of impurities through the HfSiO film into the semiconductor substrate 101 can be prevented even if a heat treatment is performed after formation of the gate insulating film 104. Moreover, oxygen deficiency in the HfSiO film, etc. can be compensated for in the gate insulating film 104, and especially in the second high-k film 105.

Nitrogen is uniformly distributed in the first high-k film 103, and is also uniformly distributed in the second high-k film 105. Thus, the nitrogen concentration abruptly changes at the interface between the first high-k film 103 and the second high-k film 105. The nitrogen concentration profile in the gate insulating film 104 can be changed by changing the thickness ratio between the first high-k film 103 and the second high-k film 105.

For example, if the ratio of the thickness T₁ of the first high-k film 103 to the thickness T₂ of the second high-k film 105 is 1 (T₁≈T₂) as shown in FIG. 1A, the nitrogen concentration abruptly changes in the center of the gate insulating film 104 in the thickness direction as shown in FIG. 1B.

If the ratio of the thickness T₁ of the first high-k film 103 to the thickness T₂ of the second high-k film 105 is higher than 1 (T₁>T₂) as shown in FIG. 1C, the nitrogen concentration abruptly changes at a position closer to the gate electrode 107 than the center of the gate insulating film 104 in the thickness direction as shown in FIG. 1D. In this case, the proportion of the first high-k film 103 in the gate insulating film 104 is higher than that in the case of FIG. 1A. Thus, diffusion of nitrogen from the gate insulating film 104 to the interface between the interface oxide layer 102 and the semiconductor substrate 101 can be suppressed as compared to the case of FIG. 1A.

If the ratio of the thickness T₁ of the first high-k film 103 to the thickness T₂ of the second high-k film 105 is lower than 1 (T₁<T₂) as shown in FIG. 1E, the nitrogen concentration abruptly changes at a position closer to the interface oxide layer 102 than the center of the gate insulating film 104 in the thickness direction as shown in FIG. 1F.

Note that the first high-k film 103 may contain a metal (a first metal) other than hafnium, and may contain, e.g., at least one of Al, La, Zr, Ti, Ta, Mg, Ge, and Y. The second high-k film 105 may contain a metal (a second metal) other than hafnium, and may contain, e.g., at least one of Al, La, Zr, Ti, Ta, Mg, Ge, and Y.

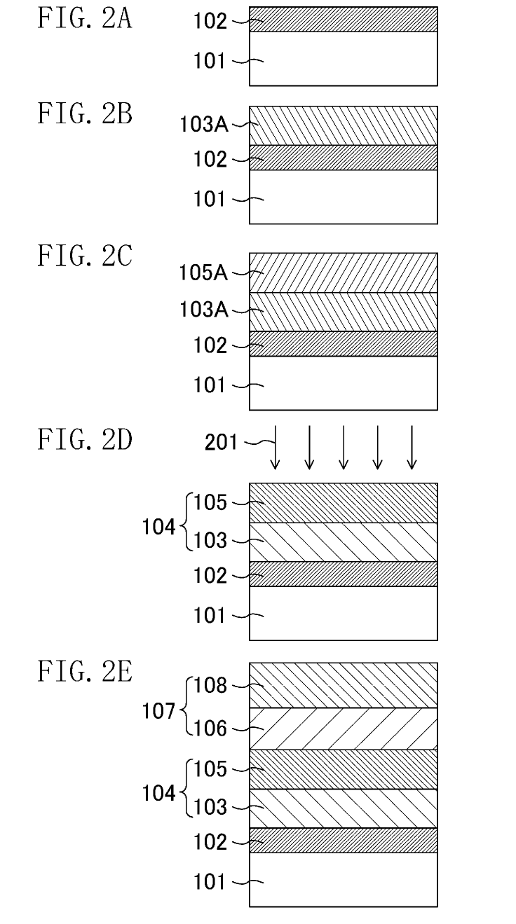

The manufacturing method of the semiconductor device according to the present embodiment will be described below with reference to FIGS. 2A-2E. FIGS. 2A-2E are cross-sectional views sequentially illustrating the steps of the manufacturing method of the semiconductor device according to the present embodiment.

First, in the step shown in FIG. 2A, the upper surface of a semiconductor substrate 101 made of silicon, etc. is cleaned with NH₄OH, H₂O₂, and H₂O. Then, a silicon oxide film or a silicon oxynitride film is formed with a thickness of 1.5 nm or less on the upper surface of the semiconductor substrate 101 by using, e.g., a thermal oxidation method. An interface oxide layer 102 is thus formed on the semiconductor substrate 101 (step (a)). The silicon oxide film or the silicon oxynitride film can be formed at a processing temperature of 700° C. to 1000° C. by using an O₂, N₂O, or NO gas.

Next, in the step shown in FIG. 2B, a first high-k material film 103A, which is a HfO₂ film or a HfSiO film, is formed on the upper surface of the interface oxide layer 102 (step (b1)).

Then, in the step shown in FIG. 2C, a second high-k material film 105A, which is a HfO₂ film or a HfSiO film, is formed on the upper surface of the first high-k material film 103A (step (b2)). The atom ratio of O to Hf in the second high-k material film 105A is equal to or lower than the atom ratio of O to Hf in the first high-k material film 103A. Preferably, the first high-k material film 103A and the second high-k material film 105A satisfy b/a≦1, where “a” represents the atom ratio of O to Hf in the first high-k material film 103A, and “b” represents the atom ratio of O to Hf in the second high-k material film 105A.

In the step shown in FIG. 2D, the surface of the second high-k material film 105A is exposed to plasma 201 containing nitrogen with the temperature of the semiconductor substrate 101 in the range of 20-150° C. Thus, the first high-k material film 103A and the second high-k material film 105A are doped with nitrogen, whereby a first high-k film 103 and a second high-k film 105 are formed, and a gate insulating film 104 formed by the first high-k film 103 and the second high-k film 105 is thus formed (step (b3)). At this time, since the first high-k material film 103A is doped with a smaller amount of nitrogen than the second high-k material film 105A, the nitrogen concentration in the first high-k film 103 is lower than that in the second high-k film 105. The nitrogen concentration in the second high-k film 105 is preferably 20 atm % or less.

Subsequently, high temperature annealing at a temperature of 800-1,100° C. may be performed in an oxygen or nitrogen atmosphere. This can make the first and second high-k films 103, 105 dense, and can prevent evaporation of nitrogen from the first and second high-k films 103, 105.

In the step shown in FIG. 2E, a TiN film, a TiAlN film, a TaC film, or a TaCN film is formed on the upper surface of the second high-k film 105. A metal gate electrode 106 is thus formed on the upper surface of the second high-k film 105. Then, a silicon film containing conductive impurities such as phosphorus, arsenic, boron, etc. is formed on the upper surface of the metal gate electrode 106. A polysilicon electrode 108 is thus formed on the upper surface of the metal gate electrode 106, whereby a gate electrode 107, which is formed by the metal gate electrode 106 and the polysilicon electrode 108, is formed.

A method for forming the first high-k film 103 and the second high-k film 105 will be described in detail below. First, a manufacturing method of the first high-k material film 103A and the second high-k material film 105A will be described.

The first high-k material film 103A and the second high-k material film 105A are preferably formed by using an atomic layer deposition (ALD) method. Specifically, in the case where the first high-k material film 103A is a HfO₂ film, the step of supplying a first gas (a gas including hafnium) to the upper surface of the interface oxide layer 102 for a first time and the step of supplying a first oxidant (including oxygen) to the upper surface of the interface oxide layer 102 for a second time can be alternately repeated. In the case where the first high-k material film 103A is a HfSiO film, the first gas and a silicon gas may be simultaneously supplied, or the silicon gas may be supplied for the first time between the step of supplying the first gas and the step of supplying the first oxidant.

Similarly, in the case where the second high-k material film 105A is a HfO₂ film, the step of supplying a second gas (a gas including hafnium) to the upper surface of the high-k material film 103A for a third time and the step of supplying a second oxidant (including oxygen) to the upper surface of the first high-k material film 103A for a fourth time can be alternately repeated. In the case where the second high-k material film 105A is a HfSiO film, the second gas and a silicon gas may be simultaneously supplied, or the silicon gas may be supplied for the third time between the step of supplying the second gas and the step of supplying the second oxidant. In the case where the first gas and the second gas are the same, and the first oxidant and the second oxidant are the same, the second time can be made longer than the fourth time. Since the second time and the fourth time are the time for which oxygen is supplied, b/a≦1 can be satisfied by making the second time longer than the fourth time. Note that the method of implementing b/a≦1 is not limited to this. As described below, the respective materials of the first and second gases may be optimized, and the respective materials of the first and second oxidants may be optimized.

For example, it is preferable to select at least one of tetrakis(dimethylamino)hafnium (TDMAHf), tetrachlorohafnium (HfCl₄), tetrakis(ethylmethylamino)hafnium (TEMAHf), and tetrakis(1-methoxy-2-methyl-2-propoxy)hafnium (Hf(MMP)₄) as the first gas and the second gas.

It is preferable to select at least one of ozone (O₃) and water (H₂O) as the first oxidant and the second oxidant.

It is preferable to select at least one of trisdimethyl amino silane (3DMAS), silicon tetrachloride (SiCl₄), and tetrakis(1-methoxy-2-methyl-2-propoxy)silicon (Si(MMP)₄) as the silicon gas.

In the present embodiment, since the first high-k material film 103A and the second high-k material film 105A have different oxygen concentrations from each other, the first high-k material film 103A and the second high-k material film 105A are doped with different amounts of nitrogen from each other. Specifically, the lower the atom ratio of oxygen to hafnium in the high-k material film is (that is, the larger the amount of oxygen deficiency in the high-k material film is), the larger the amount of nitrogen is with which the high-k material film is doped when exposed to plasma containing nitrogen. Thus, the amount of nitrogen with which the high-k material film is doped when exposed to the plasma containing nitrogen can be controlled by controlling the atom ratio of oxygen to hafnium in the high-k material film. Thus, by forming as a lower layer a high-k material film (i.e., the first high-k material film 103A) having a higher atom ratio of oxygen to hafnium and forming as an upper layer a high-k material film (i.e., the second high-k material film 105A) having a lower atom ratio of oxygen to hafnium, the nitrogen concentration in a portion of the gate insulating film 104 located closer to the semiconductor substrate 101 can be made lower than that in a portion of the gate insulating film 104 located closer to the gate electrode 107. This can prevent diffusion of nitrogen from the gate insulating film 104 to the interface between the semiconductor substrate 101 and the interface oxide layer 102. Since the first and second high-k films 103, 105 contain nitrogen, crystallization of the first and second high-k films 103, 105 and phase separation in the first and second high-k films 103, 105 can be suppressed even if a heat treatment is performed on the semiconductor substrate 101 in a later step.

Conventionally, it is not known that the amount of nitrogen with which a high-k material film is doped can be changed by changing the atom ratio of oxygen to hafnium in the high-k material film. The inventors of the present application have arrived at the present disclosure by focusing on the method of forming the high-k material film in order to control the atom ratio of oxygen to hafnium in the high-k material film. This will be described in detail below.

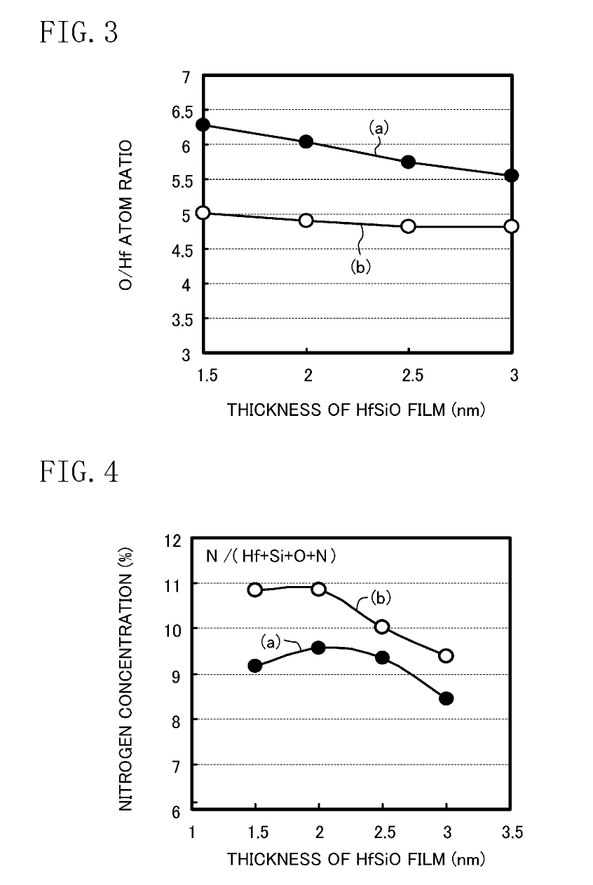

FIG. 3 is a graph showing the relation between the thickness of the HfSiO film and the atom ratio of oxygen to hafnium in the HfSiO film, as measured by using an electron probe micro-analyzer (EPMA). Each of lines (a) and (b) in FIG. 3 shows the result in the case where the HfSiO film was formed by using an ALD method, and a material gas of line (a) is different from that of line (b).

Specifically, line (a) in FIG. 3 shows the result in the case where the HfSiO film was formed by using TDMAHf as the gas including hafnium, 3DMAS as the silicon gas, and ozone as the oxidant. Line (b) in FIG. 3 shows the result in the case where the HfSiO film was formed by using HfCl₄ as the gas including hafnium, SiCl₄ as the silicon gas, and H₂O as the oxidant.

Note that in the case where the HfSiO film is formed by using a gas (3DMAS) including carbon as the silicon gas, about 3 atm % or less of carbon may remain in the HfSiO film. In the case where the HfSiO film is formed by using a gas (SiCl₄) including chlorine as the silicon gas, about 3 atm % or less of chlorine may remain in the HfSiO film. When the HfSiO film is formed by using the gas including chlorine as the silicon gas, defects are produced in the HfSiO film if chlorine is evaporated when depositing the HfSiO film. Since the atomic radius of chlorine is larger than that of nitrogen, defects larger than the atomic radius of nitrogen are produced in the HfSiO film. Thus, such a HfSiO film can be doped with a larger amount of nitrogen.

Referring to lines (a) and (b) in FIG. 3, the atom ratio of oxygen to hafnium in the HfSiO film is about 5.5-6 in the case where the HfSiO film was formed by using TDMAHf as the gas including hafnium and ozone as the oxidant (line (a)), whereas the atom ratio of oxygen to hafnium in the HfSiO film is about 4.5-5 in the case where the HfSiO film was formed by using HfCl₄ as the gas including hafnium and water as the oxidant (line (b)). Thus, the graph of FIG. 3 shows that the HfSiO film shown by line (a) contains a larger amount of oxygen than the HfSiO film shown by line (b). That is, the amount of oxygen deficiency in the HfSiO film shown by line (a) is smaller than that of oxygen deficiency in the HfSiO film shown by line (b). Thus, the atom ratio of oxygen to hafnium in the HfSiO film can be changed by changing the material gas of the HFSiO film.

FIG. 4 is a graph showing the relation between the thickness of the HfSiO film and the nitrogen concentration in the HfSiO film, as measured by X-ray photoelectron spectroscopy. Each of lines (a) and (b) in FIG. 4 shows the relation between the thickness and the nitrogen concentration of the HfSiO film that was obtained by performing a heat treatment at 1,000° C. or more in a nitrogen atmosphere after exposing the high-k material film to plasma containing nitrogen. Line (a) in FIG. 4 shows the result in the case where the high-k material film shown by line (a) in FIG. 3 was used as the high-k material film. Line (b) in FIG. 4 shows the result in the case where the high-k material film shown by line (b) in FIG. 3 was used as the high-k material film.

Referring to lines (a) and (b) in FIG. 4, the HfSiO film shown by line (b) in FIG. 4 has been doped with a larger amount of nitrogen than the HfSiO film shown by line (a) in FIG. 4 by about 1-2 atm %. This result shows that the HfSiO film having a lower atom ratio of oxygen to hafnium, namely the HfSiO film having a larger amount of oxygen deficiency, is doped with a greater number of nitrogen atoms.

Based on the above results, the inventors found that a HfSiO film having a low nitrogen concentration can be formed at a position close to the semiconductor substrate 101 and a HfSiO film having a high nitrogen concentration can be formed at a position close to the gate electrode 107 by positioning the HfSiO film having a small amount of oxygen deficiency (the HfSiO film shown by line (a) in FIG. 3) at the position close to the semiconductor substrate 101, and positioning the HfSiO film having a large amount of oxygen deficiency (the HfSiO film shown by line (b) in FIG. 3) at the position close to the gate electrode 107.

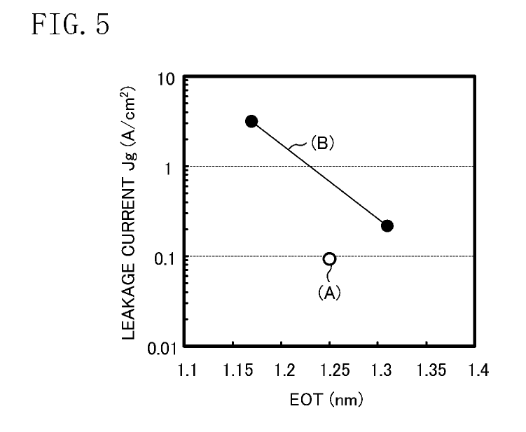

FIG. 5 is a graph showing the relation between an equivalent oxide thickness (EOT) and a leakage current Jg. The EOT refers to the thickness of an insulating film that is obtained by back calculation from gate capacitance on the assumption that the gate insulating film is made of a silicon oxide.

Point (A) in FIG. 5 shows the result in the case where the semiconductor device of the present embodiment was used. Specifically, a silicon oxide film having a thickness of 1.5 nm or less, a gate insulating film formed by first and second high-k films, and a gate electrode formed by a metal gate electrode made of TiN and a polysilicon electrode containing impurities such as phosphorus are sequentially provided on the upper surface of a semiconductor substrate made of silicon. The first high-k film is a film formed by doping with nitrogen a first high-k material film formed by using TDMAHf and ozone. The second high-k film is a film formed by doping with nitrogen a second high-k material film formed by using HfCl₄ and H₂O. The thickness ratio of the first high-k film to the second high-k film is 1:1.

Line (B) in FIG. 5 shows the result in the case where only an HfSiO film formed by using HfCl₄ and H₂O was used as the gate insulating film.

In FIG. 5, at EOT of around 1.25 nm, the leakage current Jg is 0.7 A/cm² in line (B), and is 0.1 A/cm² in line (A). This shows that in the case where a film produced by forming a HfSiO film having a high nitrogen concentration on the upper surface of a HfSiO film having a low nitrogen concentration is used as the gate insulating film, the leakage current can be reduced by about 1/7 times as compared to the case where only a HfSiO film having a high nitrogen concentration is used as the gate insulating film.

Advantages of the present embodiment will be described below.

In the present embodiment, the gate insulating film 104 is formed by the first high-k film 103 and the second high-k film 105, and the nitrogen concentration in the first high-k film 103 is lower than that in the second high-k film 105. Thus, diffusion of nitrogen into the semiconductor substrate 101 can be prevented as compared to the case where the gate insulating film is formed by only the second high-k film 105. Accordingly, bonding of nitrogen with semiconductor of the semiconductor substrate 101 can be suppressed. This can improve characteristics of the semiconductor device. For example, the leakage current can be significantly reduced as shown in FIG. 5.

Moreover, thermal stability of the gate insulating film 104 can be improved as compared to the case where the gate insulating film is formed by only the first high-k film 103. Thus, crystallization and phase separation can be suppressed in each of the first high-k film 103 and the second high-k film 105.

The present embodiment may have the following configuration.

The semiconductor device of the present embodiment preferably includes a sidewall, an extension region, a source/drain region, a silicide layer, etc. Specifically, it is preferable that the sidewall be formed on a side surface of the gate electrode 107, that the extension region be formed below a region on a lateral side of the gate electrode 107 in the semiconductor substrate 101, that the source/drain region be formed below a region on a lateral side of the sidewall in the semiconductor substrate 101, and that the silicide layer be formed on the upper surface of the gate electrode 107 and on the upper surface of the source/drain region.

It is preferable that the manufacturing method of the semiconductor device of the present embodiment further include the step of forming the sidewall on the side surface of the gate electrode 107, the step of forming the extension region below the region on the lateral side of the gate electrode 107 in the semiconductor substrate 101, the step of forming the source/drain region below the region on the lateral side of the sidewall in the semiconductor substrate 101, and the step of forming the silicide layer on the gate electrode 107 and on the source/drain region.

In the manufacturing method of the semiconductor device of the present embodiment, the first and second high-k material films may be formed by using a metal organic chemical vapor deposition method.

As described above, the semiconductor device and the manufacturing method thereof according to the present disclosure are preferably used in various electronic apparatuses using a semiconductor integrated circuit.

What is claimed is:

1. A semiconductor device, comprising:
a semiconductor substrate;
an interface oxide layer provided on an upper surface of the semiconductor substrate;
a gate insulating film provided on an upper surface of the interface oxide layer; and
a gate electrode provided on an upper surface of the gate insulating film, wherein the gate insulating film has
a first high-k film provided on the interface oxide layer and containing nitrogen, and
a second high-k film provided on the first high-k film and containing nitrogen, and
the first high-k film has a lower nitrogen concentration than the second high-k film.

2. The semiconductor device of claim 1, wherein
the first high-k film contains hafnium and oxygen,
the second high-k film contains hafnium and oxygen, and
the first high-k film and the second high-k film satisfy b/a 1, where “a” represents an atom ratio of the oxygen to the hafnium in the first high-k film, and “b” represents an atom ratio of the oxygen to the hafnium in the second high-k film.

3. The semiconductor device of claim 2, wherein
the first high-k film contains a first metal different from the hafnium,
the second high-k film contains a second metal different from the hafnium, and
the first and second metals are at least one of Al, La, Zr, Ti, Ta, Mg, Ge, and Y.

4. The semiconductor device of claim 1, wherein
in a case where the first high-k film is thicker than the second high-k film, the nitrogen concentration abruptly changes at a position closer to the gate electrode than a center of the gate insulating film in a thickness direction.

5. The semiconductor device of claim 1, wherein
in a case where the first high-k film is thinner than the second high-k film, the nitrogen concentration abruptly changes at a position closer to the interface oxide layer than a center of the gate insulating film in a thickness direction.

6. A method for manufacturing a semiconductor device, comprising the steps of:
(a) providing an interface oxide layer on an upper surface of a semiconductor substrate;
(b) providing a gate insulating film on an upper surface of the interface oxide layer; and
(c) providing a gate electrode on an upper surface of the gate insulating film, wherein
the step (b) includes the steps of
(b1) providing a first high-k material film on the interface oxide layer,
(b2) providing a second high-k material film on the first high-k material film, and
(b3) doping the first high-k material film with nitrogen to form a first high-k film, and doping the second high-k material film with nitrogen to form a second high-k film having a higher nitrogen concentration than the first high-k film.

7. The method of claim 6, wherein
the first high-k material film is formed by using a first gas including hafnium and a first oxidant including oxygen,
the second high-k material film is formed by using a second gas including hafnium and a second oxidant including oxygen, and
the first high-k material film and the second high-k material film are formed so as to satisfy b/a≦1, where “a” represents an atom ratio of the oxygen to the hafnium in the first high-k material film, and “b” represents an atom ratio of the oxygen to the hafnium in the second high-k material film.

8. The method of claim 7, wherein
a step of supplying the first gas to the upper surface of the interface oxide layer for a first time, and a step of supplying the first oxidant to the upper surface of the interface oxide layer for a second time are repeatedly performed in the step (b1),
a step of supplying the second gas to an upper surface of the first high-k material film for a third time, and a step of supplying the second oxidant to the upper surface of the first high-k material film for a fourth time are repeatedly performed in the step (b2),
the first gas and the second gas are the same,
the first oxidant and the second oxidant are the same, and
the second time is longer than the fourth time.

9. The method of claim 7, wherein
tetrakis(dimethylamino)hafnium is used as the first gas and ozone is used as the first oxidant in the step (b1), and
tetrachlorohafnium is used as the second gas and water is used as the second oxidant in the step (b2).
